(19) United States
(12) Patent Application Publication
(10) Pub. No.: US 2015/0236702 A1
(43) Pub. Date: Aug. 20, 2015

(54) METHOD FOR LOAD SHARE BALANCING IN A SYSTEM OF PARALLEL-CONNECTED GENERATORS USING ACCUMULATED DAMAGE MODEL

(71) Applicant: Remy Technologies, LLC, Pendleton, IN (US)

(72) Inventor: Timothy J. Alfermann, Carmel, IN (US)

(21) Appl. No.: 14/626,372

(22) Filed: Feb. 19, 2015

Related U.S. Application Data
(60) Provisional application No. 61/941,684, filed on Feb. 19, 2014.

(51) Int. Cl. H03L 5/02; G05B 13/04

(52) U.S. Cl. CPC H03L 5/02; G05B 13/04

(57) ABSTRACT

A parallel generator system having a controller using an accumulated damage model for load share balancing, and a method for using an accumulated damage model for load share balancing in a parallel generator system.

### PRIORITY CLAIM AND CROSS-REFERENCE TO RELATED APPLICATIONS

This application claims the benefit under Title 35, U.S.C. §119(e) of U.S. Provisional Patent Application Ser. No. 61/941,684 filed Feb. 19, 2014 entitled METHOD FOR LOAD SHARE BALANCING IN A SYSTEM OF PARALLEL-CONNECTED GENERATORS USING ACCUMULATED DAMAGE MODEL; and is related to U.S. patent application Ser. No. ______ entitled METHOD FOR LOAD SHARE BALANCING IN A SYSTEM OF PARALLEL-CONNECTED GENERATORS USING SELECTIVE LOAD REDUCTION filed on Feb. 19, 2015 (Attorney Docket No. 22888-0208), and U.S. patent application Ser. No. ______ entitled METHOD FOR OPTIMIZING THE EFFICIENCY OF A SYSTEM OF PARALLEL-CONNECTED GENERATORS filed on Feb. 19, 2015 (Attorney Docket No. 22888-0210), the entire disclosures of which are incorporated herein by reference.

### BACKGROUND

The present disclosure generally relates to systems and methods for generating and distributing electrical power, and more particularly such systems and methods which involve multiple electrical generators connected in parallel.

Typically, a generator is a rotary electric machine of well-known type having a stator surrounded by a rotor that is driven through a belt or shaft by a prime mover (e.g., an engine) to electromagnetically induce electrical current in conductive windings of the stator, whereby mechanical power is converted into electrical power. A generator may be a DC type that produces direct current or an AC type that produces an alternating current, the latter type also referred to as an alternator. Where used to charge a battery that powers an electrical system, alternator output is rectified. A parallel system of DC generators may include an invertor to convert DC generator output to AC system output power as necessary. Reference herein to a “generator” may refer to either type (i.e., DC or AC), unless an alternator is specified.

Parallel generator systems, wherein multiple generators one type (i.e., DC or AC) are electrically connected to each other in parallel, may be adapted for use in stationary installations, usually to provide backup power for a building or campus, or in mobile installations, and may be a primary power source for charging batteries that provide electrical power for various types of vehicles, such as over-the-road tractors or large buses, for example.

Some parallel generator systems employ a plurality of prime movers to drive the multiplicity of generators. For example, an engine may be dedicated to driving only a respective one of the multiplicity of parallel-connected generators, as is typical in large stationary backup power systems.

Other parallel generator systems, particularly those used in vehicles, employ a single engine to drive the multiplicity of generators. For example, the single engine of an over-the-road tractor or large bus drives each of the multiplicity of parallel-connected generators, which are typically alternators mounted to the engine and driven by the crankshaft through a common belt. Such vehicle-based systems of parallel-connected alternators typically provide rectified DC power to a battery (or multiple batteries) that provides power to the vehicle's electrical system. The multiple alternators may be identical to each other, and may be driven at a common speed that is a ratio of the engine crankshaft speed. The output of the stator windings of each alternator providing power to the generator system (i.e., each active generator) is normally controlled by a single voltage regulator common to all alternators in the system, or a single, dedicated voltage regulator for that respective alternator. The strength of each rotor's moving magnetic field, which induces current flow in the stator windings of the surrounding stator to generate alternator output voltage, is controlled by the voltage regulator(s).

Parallel generator systems are well-known for ensuring an uninterrupted supply of power and have significant advantages over single large generator units in areas of cost effectiveness, flexibility, expandability, ease of maintenance and serviceability, and reliability.

The individual generator units operating in parallel systems are typically of smaller capacities, and may be identical or of variable output. In either case, these units can be connected in parallel with paralleling switchgear to achieve maximum output during peak requirement or the desired minimal output during other times. Often, each generator has its own digital microcontroller (referred to herein as a generator controller) which may be a plug and play device. Each of the generator controllers controls the operation of its respective individual generator unit, and cooperates in the operation of the overall parallel system, which may be controlled by an optionally included master controller. The generators may coordinate among themselves or, optionally, may designate a system master controller that is either internal to one generator or an external electronic control unit.

Using multiple generator units in parallel offers greater flexibility than using a single large-sized generator of a high capacity. Multiple smaller generators operating in parallel do not need to be grouped together and can be distributed such that they are remotely located from each other and do not require a single, large space, as would be needed in the case of a single, larger generator. Furthermore, it is often difficult when sizing generators to match load requirements to accurately project increases in load and adequately plan for anticipated additional loads; by operating generators in parallel, variations in load can be relatively easy to accommodate by adding additional parallel-connected generators for additional power supply provided. Thus, by operating generators in a parallel system, it is easier to allow for an increase in the load requirement. Moreover, if a generator unit in the parallel system breaks down or requires maintenance, that individual unit can be removed from service, and repaired or replaced, without disrupting the functioning of the other generator units in the system.

As those of ordinary skill in the art appreciate, to avoid damage the introduction (or reintroduction) of an incoming alternator to active service within a parallel generator system requires its synchronization, as closely as possible, with the other, operating alternators of the system, before they are interconnected through a common bus. Synchronization of an incoming alternator may be accomplished by connecting one operating alternator of the system to the bus (referred to as the bus alternator), and then synchronizing the incoming alternator to the bus alternator before closing the incoming alternator's main power contactor. Typically, the alternators are synchronized when: they have equal terminal voltages (setpoints), which may be achieved through adjustment of the incoming alternator's field strength; they are of equal frequency, which may be achieved through adjustment of the incoming alternator's rotational speed (though usually not called for in vehicle-based system where identical alternators are driven by the engine crankshaft through a common belt); and their phase voltages are in proper relation. Automatic synchronizing equipment is also known to those of ordinary skill in the art and can be utilized in many situations for bringing an alternator into active service in a parallel system. The above synchronization functions are typically regulated by the generator controllers and/or the optional master controller. The synchronization of DC type generators is relatively simpler, as it may be limited to equalizing their voltage setpoints.

The redundancy inherent in parallel operation of multiple generators provides greater reliability than is offered by a single generator unit for critical loads. If one unit fails, the critical loads are redistributed among other units in the system, typically on a priority basis. In many applications, critical loads needing the highest degree of reliable power account for only a fraction of the overall power generated by the system, and parallel systems provide the redundancy necessary to maintain power to critical loads even if one of its generator units fails. The redundancy inherent in a parallel system thus provides multiple layers of protection and ensures an uninterrupted supply of power for critical circuits.

In a parallel generator system, the entire load is shared by all of the parallel-connected generators operating in the system, i.e., the active generators. In prior systems, load sharing between the active, or operating, generators of the system is typically done to ensure all of these active generators contribute the same power toward the system load, or so that they all share the same voltage setpoint. This approach, however, ignores the fact that some generator units may be deactivated for significant periods over the life of the system, and can result in these deactivation periods not being equally allocated among the multiplicity of generators.

Further, although each of the multiplicity of parallel-connected generators may be co-located and operate under similar environmental conditions, oftentimes various ones of the multiplicity of parallel-connected generators, whether part of the original system design or subsequently added, are located remotely from the others and operate under significantly different conditions. For example, one of the generators of a parallel system may operate under relatively harsher conditions than one or more of the others and consequently suffer relatively greater accumulated damage, whereby it is relatively more prone to fail during system operation. Continuing reliance as usual on the operation of a generator unit which has relatively greater likelihood of failure can result in its needing replacement or repair unpredictably and inconveniently. Moreover, the unpredicted failure of such a generator unit while a parallel generator system is under a high system load conditions when, albeit temporarily, all generators in the system may be operating, can undermine system reliability.

More efficient utilization of parallel-connected generators, and thus improved reliability and efficiency of a parallel generator system would be facilitated by systems and methods that more fully utilize each of the various multiple generators of a parallel generator system over the life of the system. Consequently, the useful life of the system could thus be maximized. Likewise, more efficient utilization of those generators, and improved system reliability and efficiency would be facilitated by systems and methods that better predict which of the multiplicity of generators in the system is relatively more prone to fail in operation, and are able to selectively choose which of the parallel-connected generators shall be active and inactive on the basis of their relative likelihoods to soon fail in operation.

### SUMMARY

The present disclosure provides a parallel generator system having a controller using an accumulated damage model for load share balancing, and a method for using an accumulated damage model for load share balancing in a parallel generator system.

The present disclosure provides a parallel generator system having a service life and including a system bus adapted for connection to an electrical load, a plurality of generator units electrically connectable in parallel to the system bus, and a plurality of controllers. Each generator unit is activated when providing electrical power to the system bus, and the accumulated damage of each generator unit is modeled during the system service life. One or more of the generator units is selectively deactivated by a controller during a portion of the system service life on the basis of the accumulated damage of the generator unit, whereby load share balancing among the plurality of generator units occurs over the system service life.

The present disclosure also provides a method for load share balancing among a plurality of generator units in a parallel generator system having as service life. The method includes: defining the accumulated damage of each generator unit with an accumulated damage model; and using at least one controller for selectively deactivating one or more of the generator units during a portion of the system service life on the basis of the accumulated damage of the generator unit. Consequently, load share balancing among the plurality of generator units occurs over the system service life.

The disclosed system and method also facilitate better predicting which of a multiplicity of parallel-connected generators is relatively more prone to fail in operation, and selectively choosing which of the parallel-connected generators shall be active and inactive in the system, on the basis of their relative likelihoods of failure.

In accordance with the teachings of the present disclosure, more efficient utilization of the generator units of a parallel generator system is facilitated, thereby improving system reliability and efficiency vis-à-vis prior parallel generator systems, and maximizing the service life of the system.

The accumulated damage criterion of each generator unit in a parallel system reflects its operation under conditions understood to adversely affect its continued reliability. The probability of generator failure during operation increases with its time in operation, particularly under one or more stressing conditions understood to correlate with a shortening of its service life. Such conditions typically include, for example, operation under high temperature. In other words, for a given operating period, the failure of a generator unit operating at relatively higher temperatures is likely to occur before the failure of that unit operating at lower temperatures. Generator temperature can be affected, for example, by its design, capacity, component materials, location, installation placement, cooling provisions, and electrical loading, and other factors. If, over the accumulated time in operation, a generator unit's temperature is significantly higher rather than lower, it is generally understood by those of ordinary skill in the art, that the likelihood of earlier failure will be greater. This may be due to greater wear and material degradation experienced with operation at higher temperatures influenced by one or more of the above-mentioned factors.

Thus, a generator unit's operating temperature history can serve as an accumulated damage equivalent, and be indicative of the unit's proneness to failure or continued reliability vis-à-vis another selectable generator unit that would experience similar electrical loading in future service. As noted above, the entire electrical load is shared by all operating generators of a parallel generator system. Thus, the load to be carried substantially equally by the parallel-connected generator units selected for active service in the system, whereas the introduction of non-selected generator unit(s), predicted to be relatively less reliable, is deferred until necessitated by electrical demand on the system.

In accordance with the teachings of the present disclosure, the reliability and efficiency of a parallel generator system can be beneficially affected by selectively choosing from its multiplicity of parallel-connected generators, which generator unit(s) to regularly keep in operation (i.e, to regularly be among the active units), and which generator unit(s) to keep from being regularly brought into operation (i.e., to regularly be among the inactive units).

In one embodiment of the present disclosure, the generator unit with the highest accumulated damage is the last of the multiplicity of parallel-connected generators to be introduced into active service in the system. Accordingly, the accumulated damages of all generators in the system may tend towards equalization, resulting in maximal system life with minimal interim, unpredicted, and inconvenient generator unit failures that undermine system reliability and efficiency.

Each parallel connected alternator uses its temperature to calculate an accumulated damage equivalent. Generator units of the system are ranked in order from least damage to greatest. The least damaged units are activated first, with the most damaged units activated last.

In certain parallel generator system embodiments according to the present disclosure, the generator controller of each generator serially communicates with the system's optionally included master controller. Compared to parallel communication networks, serial communication networks generally afford reduced system costs and complexity, and can better accommodate longer data transmission distances and smaller controller packaging spaces, further contributing to system cost effectiveness and reliability. Moreover, serial communication networks are often required by customers of parallel generator systems, and sometimes can be more easily and less expensively incorporated into a preexisting communication infrastructure.

### BRIEF DESCRIPTION OF THE DRAWINGS

The above-mentioned aspects and other characteristics and advantages of a system and/or method according to the present disclosure will become more apparent and will be better understood by reference to the following description of exemplary embodiments taken in conjunction with the accompanying drawings, wherein:

FIG. 1 depicts a schematic of an example parallel generator system embodiment according to the present disclosure; and

FIG. 2 shows an example of an algorithm for use in a method embodiment according to the present disclosure.

### DETAILED DESCRIPTION OF EXEMPLARY EMBODIMENT(S)

The embodiments of the present invention described below are not intended to be exhaustive or to limit the invention to the precise forms disclosed in the following detailed description. Rather, the embodiments are chosen and described so that others skilled in the art may appreciate and understand the principles and practices of the present invention.

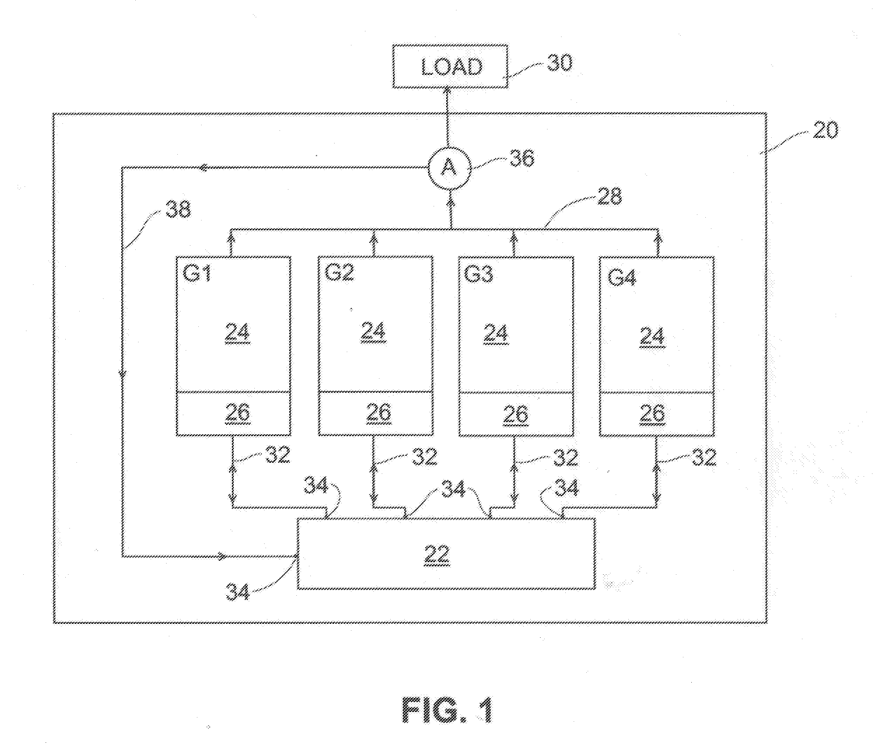

FIG. 1 schematically shows an example parallel generator system embodiment connected to an electrical load. Depicted system 20 includes master controller 22, and four parallel-connected generator units 24, respectively designated G1, G2, G3, and G4, each with its own generator controller 26. As discussed further below, the inclusion of master controller 22 is optional; the generator controller(s) 26 of one generator unit 24, or of the multiplicity of generator units 24, may be adapted to carry out the method of load share balancing disclosed herein. The generator units 24 may be commonly driven by a single prime mover, or each may be driven independently of the others by a separate prime mover. The generator units 24 may also be of either DC or AC type.

In the depicted embodiment, the optionally-included master controller 22 is separate and located remotely from each of generator units 24. Alternatively, in some embodiments the master controller 22 and the generator controller 26 of one of the generator units 24 (which may then be considered the master generator unit) can be integrated into a combined master/generator controller. As a further alternative, in some embodiments the intercommunicating generator controllers 26 of the multiplicity of generator units 24 included in system 20 can cooperatively perform the herein-disclosed method and decide between themselves which of the generator units 24 shall be affected (i.e., selectively activated or deactivated) according to the disclosed method. In such embodiments, the need for a separate master controller 22 and its attendant cost and packaging considerations may therefore be avoided.

The generator units 24 are each electrically connected to a system bus 28 when introduced into active service in the system 20. By becoming connected to the system bus 28, a driven generator unit 24 becomes active; active generator units 24 are parallel-connected to each other through the bus 28, and power generated by each generator unit 24 is transferred to the system load 30 through the bus 28.

In the depicted embodiment, regardless of whether active or inactive, each of the generator controllers 26 is individually in serial communication with the master controller 22 through a respective serial communication cable 32. From the perspective of a generator controller 26, and as is typical of serial communication concepts, each serial communication cable 32 has, in addition to its ground line, a transmit line over which data is communicated from the generator controller 26 to the system master controller 22, and a receive line over which data is communicated from the system master controller 22 to the generator controller 26. Each generator controller 26 is connected through its respective cable 32 to its respectively associated serial port 34 of the master controller 22. Alternatively, in some embodiments the communication cables 32 could be daisy-chained, such as those in which master controller 22 is omitted as discussed above.

An ammeter 36 may be provided between the system bus 28 and the system load 30, whereby the electric current provided by the system 20 to the load 30 is measured and provided, in the depicted embodiment, as an input to the master controller 22 for determining the magnitude of the load 30. Such an ammeter 36 may also be in serial communication with the master controller 22 via a serial communication cable 38. Alternatively, in some embodiments, the portion of load 30 borne by each active generator unit 24 can be measured by its generator controller 26, and these load portions summed up. For example, in some embodiments where the generator units are alternators, current can be determined from the duty cycle on all active alternator voltage regulators. Thus current, and thus the load 30, can be determined through measurement internal to the active generator unit(s) 24.

In one embodiment, the system's active generators 24 have a common, known voltage setpoint Vₛₑₜ, whereby the load's total power demand on the system 20 may be determined by the master controller 22 using the current drawn by the load 30, as measured by and communicated from the ammeter 36. Alternatively, in another embodiment, different active generators 24 have respectively different voltage setpoints. Regardless of whether the active generator units 24 have a single, common voltage setpoint, or various different voltage setpoints, the method described herein ensures substantially equal thermal load sharing between all generators 24 of the system 20 over time.

Based on the measured power demand on the system 20, its master controller 22 continually determines the number of generators 24 required to be active, N_{active}. The master controller 22 and the individual generator controllers 26 cooperate to selectively activate and deactivate the individual generator units 24, as discussed further below.

As discussed above, accumulated damage reflects the amount of service life used, and thus the likelihood of failure with further operation under certain stresses (e.g., thermal loads) can be predicted by determining its accumulated damage. In accordance with one embodiment, the accumulated damage for each generator may be determined by Miner's Rule. Miner's Rule is a simple cumulative damage model stating that, under a linear damage hypothesis and irrespective of the order of stress loading, if there are k different stress levels and the average number of cycles to failure at the ith stress level, Sᵢ, is Nᵢ, then the damage fraction, C, is:

$${\sum }_{i = 1}^{k} \frac{{n}_{i}}{{N}_{i}} = C$$

wherein nᵢ is the number of cycles accumulated at stress Sᵢ, and C is the fraction of life consumed by exposure to the cycles at the different stress levels. In the present embodiment, the different stress levels correlate to respective operating times at various thermal loads, represented by the generator's operating temperature monitored and recorded by its respective generator controller 26. In general, when the damage fraction C reaches 1, the generator unit 24 has reached the end of its useful service life, and its failure should be considered imminent if it has not yet occurred.

Each generator's damage fraction C is communicated via its transmit line to the system master controller 22, where it is received at the associated serial port 32. For example, if the system 20 includes four parallel-connected generator units 24, G1, G2, G3, G4, as shown in FIG. 1, the generator controller 26 of each will calculate, record and maintain a fraction of life histogram, and continually transmit its respective fraction of life C₁, C₂, C₃, C₄ via its respective transmit line to the master controller 22.

In a method embodiment, the system master controller 22 performs an algorithm which, based on the respective fractions of life received from the multiple generator controllers 26 and the number of active generator units 24 needed to accommodate the load 30, ranks the multiple generator units 24 of the system 20 for their selection for introduction to or removal from active service, deferring activation of or removing those generator units 24 predicted to soonest fail unless and until needed to help support the load 30.

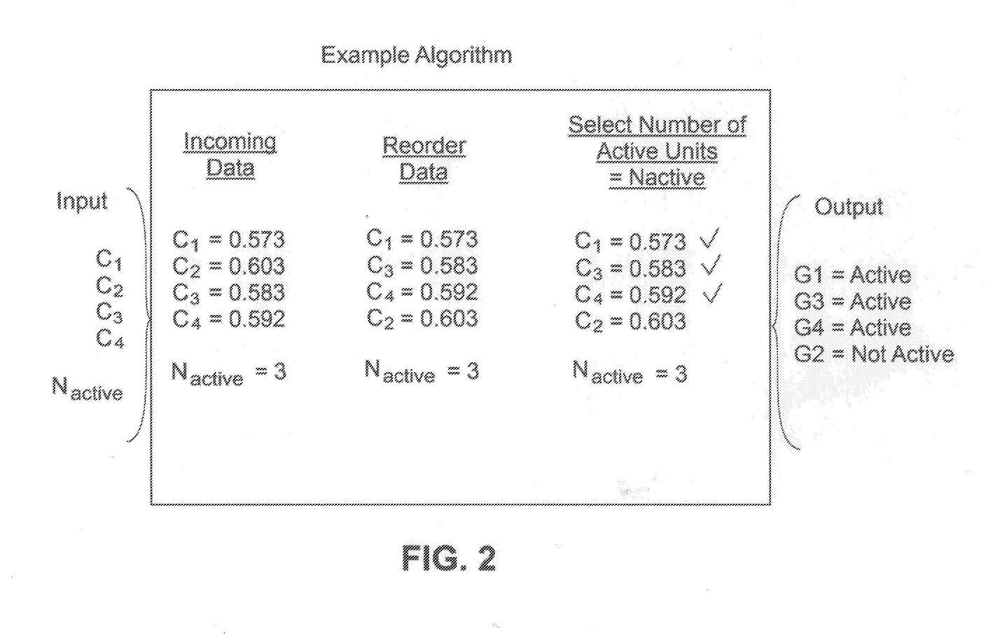

FIG. 2 shows an example of this method where fractions of life C₁, C₂, C₃, and C₄, received from generator controllers 26, and the number of generators 24 required to be active, N_{active}, determined by calculating power requirements based on the measured current drawn by the load 30 and the known voltage setpoint(s) Vₛₑₜ, are inputs to the algorithm. Referring to FIG. 2, the algorithm receives these inputs as incoming data; reorders the fractions of life data from least to greatest, thereby ranking the generator units 24; and from the entire number of ranked generator units 24, selects N_{active} of the generator units associated with the lowest fractions of life for active duty. In the example of FIG. 2, N_{active} is three, and generator units G1, G3, and G4, having the lowest fractions of life C₁, C₃, and C₄, respectively, are selected as the generator units 24 to be active in system 20; generator unit G2, with the highest fraction of life value C₂, is selected to be not active. Although the algorithm is continually applied, these selections would be maintained until either N_{active} changes, the fraction of life rankings between C₁, C₂, C₃, and C₄ change, an active generator 24 unexpectedly fails, or perhaps an additional generator 24 (e.g., a unit G5) having a fraction of life value (e.g., C₅) that is lower than any of C₁, C₃, or C₄ is added to the system 20.

The following is a list of preferred embodiments according to the present disclosure: 1. A parallel generator system having a service life and including:

a system bus adapted for connection to an electrical load;

a plurality of generator units electrically connectable in parallel to the system bus, each generator unit activated when providing electrical power to the system bus, the accumulated damage of each generator unit being modeled during the system service life; and

a plurality of controllers;

wherein one or more of the generator units is selectively deactivated by a controller during a portion of the system service life on the basis of the accumulated damage of the generator unit, whereby load share balancing among the plurality of generator units occurs over the system service life.

2. The parallel generator system of embodiment 1, wherein selective deactivation of one or more generator units is determined by a controller on the basis of the load-required number of active generator units and the relative modeled accumulated damages of the plurality of generator units.
3. The parallel generator system of embodiment 2, wherein each generator unit has a respective generator controller, each generator controller defining a controller,

wherein the accumulated damage of each generator unit is modeled by its respective generator controller,

wherein an indicator of the modeled accumulated damage of each generator unit is communicated by the respective generator controller to a controller, and

wherein a controller selectively deactivates one or more generator units based on the load-required number of active generator units and a ranking of the respective indicators of the modeled accumulated damages of the plurality of generator units.

4. The parallel generator system of embodiment 3, wherein the indicator communicated by each generator controller is the damage fraction C representing the fraction of generator unit life consumed under Miner's Rule by exposure of the respective generator unit to cycles at different stress levels.
5. The parallel generator system of embodiment 4, wherein the different stress levels correlate to respective operating times at various thermal loads represented by the operating temperatures of the respective generator unit.
6. The parallel generator system of embodiment 5, wherein the operating temperatures of each generator unit is monitored and recorded by the respective generator controller.
7. The parallel generator system of embodiment 3, wherein a controller defines an optionally included master controller in communication with each generator controller.
8. The parallel generator system of embodiment 7, wherein the optionally included master controller is separate and located remotely from each of the plurality of generator units.
9. The parallel generator system of embodiment 2, wherein during operation of the system a generator unit selectively deactivated has a comparatively higher modeled accumulated damage than any active generator unit.
10. The parallel generator system of embodiment 1, wherein the accumulated damage of each generator unit is modeled to reflect operation of that generator unit under at least one stressing condition understood to correlate with a shortening of generator unit service life.
11. The parallel generator system of embodiment 10, wherein the stressing condition includes that generator unit's respective operating temperature history.
12. A method for load share balancing among a plurality of generator units in a parallel generator system having as service life, including:

defining the accumulated damage of each generator unit with an accumulated damage model; and

using at least one controller for selectively deactivating one or more of the generator units during a portion of the system service life on the basis of the accumulated damage of the generator unit, whereby load share balancing among the plurality of generator units occurs over the system service life.

13. The method of embodiment 12, wherein deactivation of one or more generator units is selected by a controller on the basis of the load-required number of active generator units and the relative modeled accumulated damages of the plurality of generator units.
14. The method of embodiment 13, further including:

using a controller to define a generator controller of each respective generator unit to model the accumulated damage of that generator unit,

communicating an indicator of the modeled accumulated damage of each generator unit from the respective generator controller to a controller, and

selectively deactivating one or more generator units on the bases of the load-required number of active generator units and a ranking of the respective indicators of the modeled accumulated damages of the plurality of generator units.

15. The method of embodiment 14, wherein the indicator communicated by each generator controller is the damage fraction C representing the fraction of generator unit life consumed under Miner's Rule by exposure of the respective generator unit to cycles at different stress levels.
16. The method of embodiment 15, wherein the different stress levels correlate to respective operating times at various thermal loads represented by the operating temperatures of the respective generator unit.
17. The method of embodiment 14, wherein communicating an indicator of the modeled accumulated damage of each generator unit from the respective generator controller to a controller includes communicating the indicator to an optionally included master controller defined by a controller in communication with each generator controller.
18. The method of embodiment 17, wherein the optionally included master controller is separate and located remotely from each of the plurality of generator units.
19. The method of embodiment 13, further including selectively deactivating a generator unit having a comparatively higher modeled accumulated damage than any generator unit remaining active.
20. The method of embodiment 12, further including modeling the accumulated damage of each generator unit to reflect operation of that generator unit under at least one stressing condition understood to correlate with a shortening of generator unit service life.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A parallel generator system having a service life and including:
a system bus adapted for connection to an electrical load;
a plurality of generator units electrically connectable in parallel to the system bus, each generator unit activated when providing electrical power to the system bus, the accumulated damage of each generator unit being modeled during the system service life; and
a plurality of controllers;
wherein one or more of the generator units is selectively deactivated by a controller during a portion of the system service life on the basis of the accumulated damage of the generator unit, whereby load share balancing among the plurality of generator units occurs over the system service life.

2. The parallel generator system of claim 1, wherein selective deactivation of one or more generator units is determined by a controller on the basis of the load-required number of active generator units and the relative modeled accumulated damages of the plurality of generator units.

3. The parallel generator system of claim 2, wherein each generator unit has a respective generator controller, each generator controller defining a controller,
wherein the accumulated damage of each generator unit is modeled by its respective generator controller,
wherein an indicator of the modeled accumulated damage of each generator unit is communicated by the respective generator controller to a controller, and
wherein a controller selectively deactivates one or more generator units based on the load-required number of active generator units and a ranking of the respective indicators of the modeled accumulated damages of the plurality of generator units.

4. The parallel generator system of claim 3, wherein the indicator communicated by each generator controller is the damage fraction C representing the fraction of generator unit life consumed under Miner's Rule by exposure of the respective generator unit to cycles at different stress levels.

5. The parallel generator system of claim 4, wherein the different stress levels correlate to respective operating times at various thermal loads represented by the operating temperatures of the respective generator unit.

6. The parallel generator system of claim 5, wherein the operating temperatures of each generator unit is monitored and recorded by the respective generator controller.

7. The parallel generator system of claim 3, wherein a controller defines an optionally included master controller in communication with each generator controller.

8. The parallel generator system of claim 7, wherein the optionally included master controller is separate and located remotely from each of the plurality of generator units.

9. The parallel generator system of claim 2, wherein during operation of the system a generator unit selectively deactivated has a comparatively higher modeled accumulated damage than any active generator unit.

10. The parallel generator system of claim 1, wherein the accumulated damage of each generator unit is modeled to reflect operation of that generator unit under at least one stressing condition understood to correlate with a shortening of generator unit service life.

11. The parallel generator system of claim 10, wherein the stressing condition includes that generator unit's respective operating temperature history.

12. A method for load share balancing among a plurality of generator units in a parallel generator system having as service life, including:
defining the accumulated damage of each generator unit with an accumulated damage model; and
using at least one controller for selectively deactivating one or more of the generator units during a portion of the system service life on the basis of the accumulated damage of the generator unit, whereby load share balancing among the plurality of generator units occurs over the system service life.

13. The method of claim 12, wherein deactivation of one or more generator units is selected by a controller on the basis of the load-required number of active generator units and the relative modeled accumulated damages of the plurality of generator units.

14. The method of claim 13, further comprising:
using a controller to define a generator controller of each respective generator unit to model the accumulated damage of that generator unit,
communicating an indicator of the modeled accumulated damage of each generator unit from the respective generator controller to a controller, and
selectively deactivating one or more generator units on the bases of the load-required number of active generator units and a ranking of the respective indicators of the modeled accumulated damages of the plurality of generator units.

15. The method of claim 14, wherein the indicator communicated by each generator controller is the damage fraction C representing the fraction of generator unit life consumed under Miner's Rule by exposure of the respective generator unit to cycles at different stress levels.

16. The method of claim 15, wherein the different stress levels correlate to respective operating times at various thermal loads represented by the operating temperatures of the respective generator unit.

17. The method of claim 14, wherein communicating an indicator of the modeled accumulated damage of each generator unit from the respective generator controller to a controller comprises communicating the indicator to an optionally included master controller defined by a controller in communication with each generator controller.

18. The method of claim 17, wherein the optionally included master controller is separate and located remotely from each of the plurality of generator units.

19. The method of claim 13, further comprising selectively deactivating a generator unit having a comparatively higher modeled accumulated damage than any generator unit remaining active.

20. The method of claim 12, further comprising modeling the accumulated damage of each generator unit to reflect operation of that generator unit under at least one stressing condition understood to correlate with a shortening of generator unit service life.
